(19) United States
(12) Patent Application Publication
(10) Pub. No.: US 2010/0112212 A1
(43) Pub. Date: May 6, 2010

(54) ADJUSTABLE GAS DISTRIBUTION APPARATUS

(75) Inventors: Lin Zhang, San Jose, CA (US); Lun Tsuei, Mountain View, CA (US); Alan Tso, San Jose, CA (US); Tom K. Cho, Los Altos, CA (US); Brian Sy-Yuan Shieh, Palo Alto, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/604,591

(22) Filed: Oct. 23, 2009

Related U.S. Application Data
(60) Provisional application No. 61/110,210, filed on Oct. 31, 2008.

(51) Int. Cl. C23C 16/455; C23C 16/54

(52) U.S. Cl. 427/248.1; 118/723 R; 118/666; 118/663

(57) ABSTRACT

Embodiments of the present invention generally provide apparatus and methods for altering the contour of a gas distribution plate within a process chamber without breaking vacuum conditions within the chamber. In one embodiment, a central support device adjusted to vary the height of a central region of a gas distribution plate with respect to the periphery of the gas distribution plate. In another embodiment, a plurality of central support devices is adjusted to vary the height of a central region of a gas distribution plate with respect to the periphery of the plate. In yet another embodiment, a plurality of central support devices and a plurality of mid-range support devices are adjusted to vary the height of certain regions of the gas distribution plate with respect to other regions of the gas distribution plate. In one embodiment, the contour of the gas distribution plate is altered based on changes detected within the process chamber.

### CROSS-REFERENCE TO RELATED APPLICATIONS

This application claims benefit of U.S. provisional patent application Ser. No. 61/110,210, filed Oct. 31, 2008, which is herein incorporated by reference.

### BACKGROUND OF THE INVENTION

1. Field of the Invention

Embodiments of the present invention provide apparatus and methods for adjusting the contour of a gas distribution plate.

2. Description of the Related Art

As demand for larger solar panels and flat panel displays continues to increase, so must the size of substrates and chambers for processing the substrates. One method for depositing material onto a substrate for solar panels or flat panel displays is plasma enhanced chemical vapor deposition (PECVD). In PECVD, process gases are typically introduced across a gas distribution plate in a process chamber through a central gas feed orifice. The process gases diffuse through the gas distribution plate and are ignited into plasma by an RF current applied to the gas distribution plate. The plasma envelops a substrate disposed in a process region of the chamber and deposits thin films on the surface of the substrate.

As substrate sizes increase, depositing uniform films on the substrate becomes increasingly difficult. Therefore, there is a need in the art for an apparatus and method for adjusting the contour of a gas distribution panel in a process chamber to provide improved film deposition uniformity.

### SUMMARY OF THE INVENTION

In one embodiment of the present invention, a process chamber comprises a chamber body having walls, a bottom, and a backing plate defining a pressure tight volume, a gas distribution plate coupled to the backing plate about a peripheral region thereof, a central support member coupled to an upper surface of the gas distribution plate and extending through the backing plate, a sealing member disposed between the backing plate and the central support member, a lift mechanism disposed outside of the pressure tight volume and coupled to the central support member to move the central support member with respect to the backing plate, and an actuator disposed outside of the pressure tight volume configured to activate the lift mechanism.

In another embodiment, a process chamber comprises a chamber body having walls, a bottom, and a backing plate defining a pressure tight volume, a gas distribution plate coupled to the backing plate about a peripheral region thereof, a first plurality of support members coupled to an upper surface of the gas distribution plate and extending through the backing plate, a sealing member disposed between each support member and the backing plate, and one or more first actuators disposed outside of the pressure tight volume and coupled to at least one of the first plurality of support members for moving the support member with respect to the backing plate. In one embodiment, the first plurality of support members are capable of being actuated from outside of the pressure tight volume to move regions of the gas distribution plate coupled to each support member.

In yet another embodiment of the present invention, a method for processing a substrate comprises placing the substrate onto a substrate support opposite a gas distribution plate inside a process chamber, establishing a vacuum processing condition inside the process chamber, introducing a process gas into the chamber, and automatically altering the surface contour of the gas distribution plate without altering the pressure condition within the process chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, cross-sectional view of a process chamber according to one embodiment of the present invention.

FIG. 2 is a schematic, cross-sectional view of a process chamber according to another embodiment of the present invention.

FIG. 3 is a schematic, top view of a backing plate of a process chamber according to one embodiment of the present invention.

FIG. 4 is a schematic, top view of a backing plate of a process chamber according to another embodiment of the present invention.

FIGS. 5A, 5B, and 5C schematically depict examples of altering the contour of the gas distribution plate according to certain embodiments of the present invention.

### DETAILED DESCRIPTION

During processing, thermal conditions within a process chamber may cause deformity in or drooping of a gas distribution plate disposed therein. Additionally, thermal conditions within the process chamber may cause deformity in a substrate support disposed within the process chamber for supporting the substrate. Either condition may result in differences in the distance between the substrate and the gas distribution plate across the surface of the substrate, which may lead to deposition non-uniformities.

Embodiments of the present invention generally provide apparatus and methods for altering the contour of a gas distribution plate within a process chamber without breaking vacuum conditions within the chamber. In one embodiment, a central support device is adjusted to vary the height of a central region of a gas distribution plate with respect to the periphery of the gas distribution plate. In another embodiment, a plurality of central support devices is adjusted to vary the height of a central region of a gas distribution plate with respect to the periphery of the plate. In yet another embodiment, a plurality of central support devices and a plurality of mid-range support devices are adjusted to vary the height of certain regions of the gas distribution plate with respect to other regions of the gas distribution plate. In one embodiment, the contour of the gas distribution plate is altered based on changes detected within the process chamber. By providing adjustment of the contour of a gas distribution plate within a process chamber without breaking vacuum, the thickness of a film deposited on certain regions of a substrate within the chamber may be adjusted and tuned in situ resulting in improved deposition uniformity with minimal process interruptions.

The invention is illustratively described below in reference to a chemical vapor deposition system, processing large area substrates, such as a PECVD system, available from Applied Materials, Inc., Santa Clara, Calif. However, it should be understood that the apparatus and method may have utility in other system configurations.

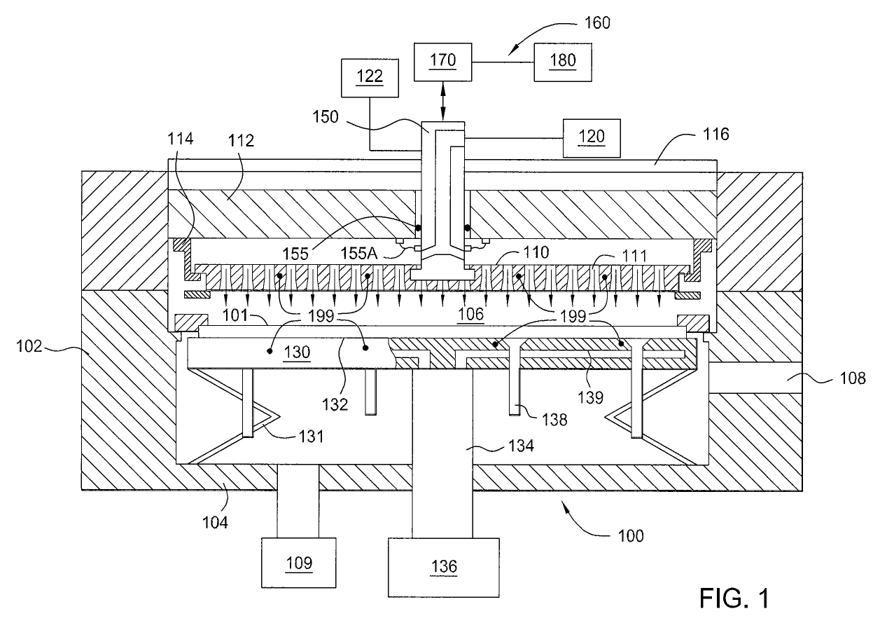

FIG. 1 is a schematic, cross-sectional view of a process chamber 100 according to one embodiment of the present invention. The process chamber 100 generally includes walls 102, a bottom 104, a gas distribution plate 110, and a substrate support 130, which cumulatively define a process volume 106. The process volume may be accessed through a valve opening 108 such that a substrate 101 may be transferred into and out of the process chamber 100. The substrate support 130 includes a substrate receiving surface 132 for supporting the substrate 101 and a stem 134, which may be coupled to a lift system 136 to raise and lower the substrate support 130. Lift pins 138 are moveably disposed through the substrate support 130 to move the substrate 101 to and from the substrate receiving surface 132. The substrate support 130 may also include heating and/or cooling elements 139 to maintain the substrate support 130 at a desired temperature. The substrate support 130 may also include RF return straps 131 to provide a shortened return path for RF current from the substrate support 130 to an RF power source 122.

In one embodiment, the gas distribution plate 110 is coupled to a backing plate 112 at its periphery by a suspension 114. The gas distribution plate 110 includes a plurality of gas passages 111 disposed therethrough. A gas source 120 is coupled to the backing plate 112 to provide gas through the backing plate 112 and through the gas distribution plate 110 to the substrate 101. A vacuum pump 109 is coupled to the process chamber 100 to control the process volume 106 at a desired pressure. The RF power source 122 is coupled to the backing plate 112 to provide an RF current to the gas distribution plate 110 so that an electric field is created between the gas distribution plate 110 and the substrate support 130 such that plasma may be generated from process gases disposed between the gas distribution plate 110 and the substrate support 130. A cover plate 116 may be disposed above the backing plate 112.

In one embodiment, the gas distribution plate 110 is adjustably coupled to the backing plate 112 via a central support member 150. In one embodiment, the central support member 150 is mechanically coupled to a central region of the gas distribution plate 110, such as by a slot and key, welded, or other mating connection such that if the central support member 150 is raised or lowered, the central region of the gas distribution plate 110 is correspondingly raised or lowered.

Additionally, a sealing mechanism 155 is disposed between the central support member 150 and the backing plate 112 to maintain a pressure tight seal between the central support member 150 and the backing plate 112. In one embodiment, the sealing mechanism 155 comprises one or more o-ring seals, such as silicone elastomer seals. In another embodiment, the sealing mechanism 155 comprises a bellows 155A, such as aluminum or stainless steel bellows. Other embodiments comprise other sealing mechanisms such that the central support member 150 may be raised or lowered without affecting the pressure conditions within the process chamber 100.

In one embodiment, the central support member 150 may be raised or lowered with respect to the backing plate 112 in order to raise or lower the central region of the gas distribution plate 110 with respect to the periphery of the gas distribution plate 110. In one embodiment, the central support member 150 may be manually raised and lowered via a lift mechanism 160 disposed outside of the process chamber 100, such that the central support member 150 may be manually raised and lowered without altering vacuum or other processing conditions within the process chamber 100. In one embodiment, the lift mechanism 160 may comprise a configuration using jacking screws (not shown) to lift and/or lower the central support member 150 with respect to the backing plate 112. Other embodiments may comprise other lifting configurations, such as other screw or linear jacking configurations.

In another embodiment, the central support member 150 may be automatically raised and lowered via an actuator 170 responding to commands sent by a controller 180. In one embodiment, the actuator 170 may be a linear motor. In another embodiment, the actuator 170 may include one or more pneumatic or hydraulic cylinders. In still other embodiments, the actuator may include electric or pneumatic rotary/screw type lifting mechanisms, rotary motors, or the like. Regardless of the type of actuator 170 used, the actuator 170 and/or lift mechanism 160 are disposed outside of the process chamber 100, such that such that the central support member 150 may be manually raised and lowered without altering vacuum or other processing conditions within the process chamber 100.

The controller 180 may include a central processing unit (CPU) (not shown), memory (not shown), and support circuits (or I/O) (not shown). The CPU may be one of any form of computer processors that are used in industrial settings for controlling various system functions, substrate movement, chamber processes, and support hardware, and monitor the processes. The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the controller 180 determines which tasks are performable.

In the embodiment of the present invention described with respect to FIG. 1, the contour of the gas distribution plate 110 may be altered between concave, planar, and convex shapes according to desired process and deposition conditions. Additionally, the contour of the gas distribution plate 110 may be altered either manually or automatically without breaking vacuum within the process chamber 100. Thus, the deposition uniformity across the surface of the substrate 101 may be tuned as desired in situ resulting in improved deposition uniformity with minimal process interruptions.

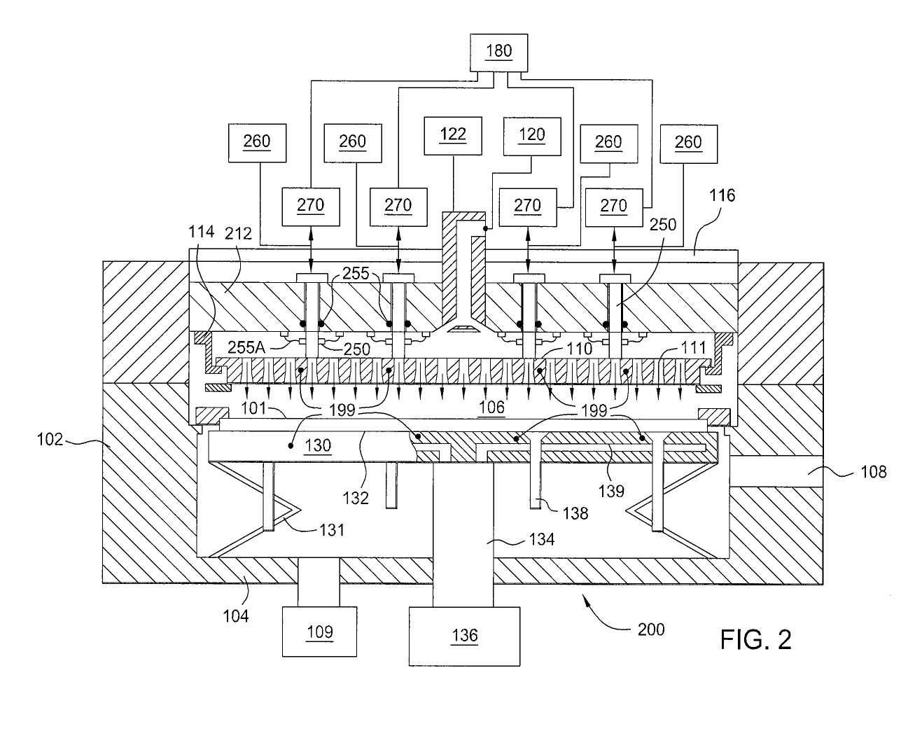

FIG. 2 is a schematic, cross-sectional view of a process chamber 200 according to another embodiment of the present invention. The process chamber 200 is similar to the process chamber 100 depicted in FIG. 1, and as such, identical reference numbers are shown to reflect identical chamber parts without further description.

In one embodiment, as shown in FIG. 2, the gas distribution plate 110 is adjustably coupled to a backing plate 212 via a plurality of support members 250. In one embodiment, the plurality of support members 250 are mechanically coupled to the gas distribution plate 110, such as by screwed, welded, or other mating connection such that when the plurality of central support members 250 are raised or lowered, the corresponding region of the gas distribution plate 110 is raised or lowered.

Additionally, each support member 250 may have a sealing mechanism 255 disposed between the support member 250 and the backing plate 212 to maintain a pressure tight seal between the support member 250 and the backing plate 212. In one embodiment, the sealing mechanism 255 comprises one or more o-ring seals, such as silicone o-rings. In another embodiment, the sealing mechanism 255 comprises a bellows 255A, such as aluminum or stainless steel bellows. Other embodiments comprise other sealing mechanisms such that each support member 250 may be raised or lowered without affecting the pressure conditions within the process chamber 200.

In one embodiment, each support member 250 may be raised or lowered with respect to the backing plate 212 in order to raise or lower the central region of the gas distribution plate 110 with respect to the periphery of the gas distribution plate 110. In one embodiment, each support member 250 may be a threaded screw member that may be either manually adjusted or automatically adjusted via an actuator 270. In one embodiment, a single actuator 270 is configured to automatically adjust a single support member 250. In another embodiment, a single actuator 270 is configured to automatically adjust more than one support member 250. In either case, adjustment may be made without breaking the vacuum seal of the process chamber 200. In one embodiment, the actuator 270 may include a motor for applying torque to a screw member of the support member 250. The actuator 270 may be controlled by the controller 180.

In one embodiment, each support member 250 may be a rod or bar comprising a material such as aluminum, stainless steel, or a ceramic material. In one embodiment, the plurality of support members 250 may be, individually or collectively, manually raised and lowered via a lift mechanism 260 disposed outside of the process chamber 200. In one embodiment, the lift mechanism 260 may comprise one or more jacking screws (not shown) to lift and/or lower the support members 250 with respect to the backing plate 212. Other embodiments may comprise other lifting configurations, such as other screw or linear jacking configurations. In one embodiment, the support member 250 may be externally threaded to mate with internally threaded apertures in the backing plate or internally threaded components not shown attached to the backing plate.

In another embodiment, the support members 250 may be, individually or collectively, automatically raised and lowered via an actuator 270 responding to commands sent by the controller 180. In one embodiment, the actuator 270 may be a linear or rotary motor. In another embodiment, the actuator 270 may include one or more pneumatic or hydraulic cylinders. In still other embodiments, each support member 250 may include the actuator 270, such as a cylinder controlled by the controller 180. Regardless of the type of actuator 270 used, the actuator 270 and/or lifting mechanism 260 are disposed outside of the process chamber 200, such that such that the support members 250 may be raised and lowered without altering vacuum or other processing conditions within the process chamber 200.

FIG. 3 schematically depicts one embodiment of a top view of the backing plate 212 from FIG. 2. In this embodiment, the support members 250 are arranged in a circular pattern about a central region of the backing plate 212. In one embodiment, the lifting mechanism 260 or the actuator 270 may raise or lower the plurality of support members 250 simultaneously or one or more at a time a substantially identical amount in order to provide a substantially convex, planar, or concave surface contour to the gas distribution plate 110. In another embodiment, the lifting mechanism 260 or the actuator 270 may adjust one or more of the central support members 250 in different amounts to provide other contours to the gas distribution plate 110.

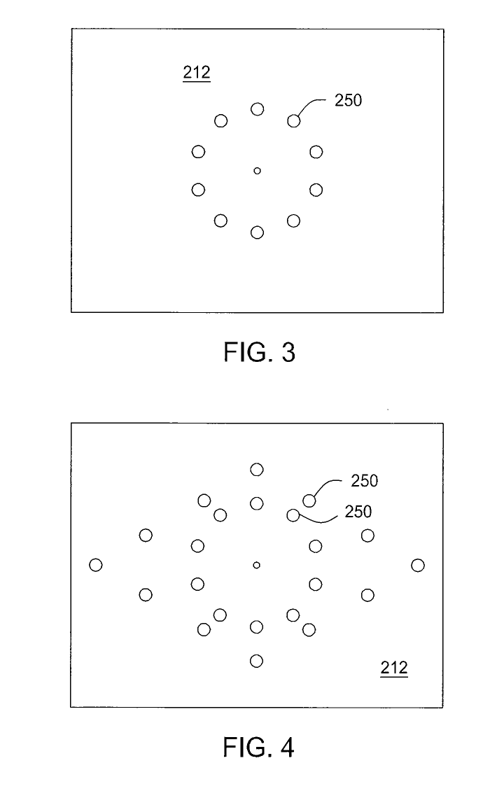

FIG. 4 schematically depicts another embodiment of a top view of the backing plate 212 from FIG. 2. In this embodiment, a first plurality of support members 250 is arranged in a circular pattern about a central region of the backing plate 212. Additionally, a second plurality of support members 250 is arranged in a pattern between the first plurality of support members 250 and the periphery of the backing plate 212. In one embodiment, the lifting mechanism 260 or the actuator 270 may raise or lower all the support members 250 a substantially identical amount to provide a desired contour to the gas distribution plate 110. In another embodiment, one lifting mechanism 260 or actuator 270 may raise or lower the first plurality of support members 250 a different amount than another lifting mechanism 260 or actuator 270 raises or lowers the second plurality of support members 250 to provide a desired contour to the gas distribution plate 110. In yet another embodiment, one or more lifting mechanisms 260 or actuators 270 may raise or lower one or more of the support members 250 different amounts to provide a contorted contour to the gas distribution plate 110.

In the embodiment of the present invention described with respect to FIGS. 2, 3, and 4, the contour of the gas distribution plate 110 may be altered between concave, planar, convex, and other contorted shapes according to the desired process and deposition conditions.

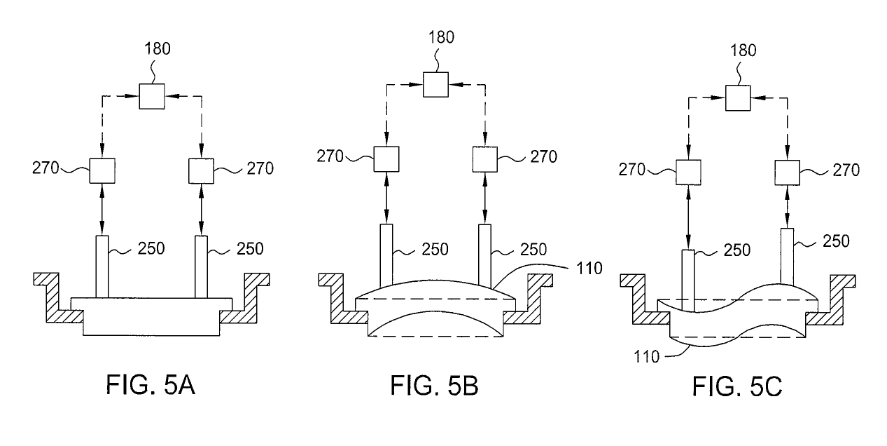

FIGS. 5A, 5B, and 5C schematically depict examples of altering the contour of the gas distribution plate 110 according to certain embodiments of the present invention. FIG. 5A schematically depicts the gas distribution plate 110 supported in a planar configuration by support members 250. FIG. 5B schematically depicts the support members 250 raising the central region of the gas distribution plate 110 to provide a concave lower surface contour to the gas distribution plate 110. FIG. 5C schematically depicts raising one region of the gas distribution plate 110, while forces another region of the gas distribution plate 110 downwardly, resulting in a contorted lower surface contour to the gas distribution plate 110. These figures are only exemplary as numerous other gas distribution plate 110 lower surface contours may be achieved by applying different forces to different regions of the gas distribution plate via the respective support members 250.

Additionally, the contour of the gas distribution plate 110 may be altered either manually or automatically without breaking vacuum within the process chamber 200. Thus, the deposition uniformity across the surface of the substrate 101 may be tuned as desired in situ resulting in improved deposition uniformity with minimal process interruptions.

In one embodiment of the present invention described with respect to FIGS. 2-4, the process chamber 100 and/or 200 may further include sensors 199 for detecting changes within the system requiring adjustment of the surface contour of the gas distribution plate 110. The sensors 199 may be temperatures sensors, position sensors, displacement sensors, or the like. For instance, sensors 199 may be embedded in either the gas distribution plate 110 or the substrate support 130 for detecting changes in the distance between the gas distribution plate 110 and the substrate support 130 across the surfaces thereof. Alternatively, sensors 199 may be embedded within the gas distribution plate 110 for detecting a change in the surface contour thereof due to process conditions within the process chamber 100 or 200. Additionally, sensors 199 may be embedded within the substrate support 130 for detecting a change in the surface contour thereof due to process conditions within the process chamber 100 or 200. In another embodiment, sensors 199 may be positioned in other locations within the chamber to detect process conditions, such as thermal conditions, requiring adjustment of the surface contour of the gas distribution plate 110. Regardless of the type or position of sensors used, the sensors may send signals to the controller 180, which in turn sends signals for adjusting the surface contour of the gas distribution plate 110, all without breaking vacuum within the process chamber 100 or 200.

While the foregoing is directed to embodiments of the present invention, other and further embodiments of the invention may be devised without departing from the basic scope thereof, and the scope thereof is determined by the claims that follow.

1. A process chamber, comprising:
a chamber body having walls, a bottom, and a backing plate defining a pressure tight volume;
a gas distribution plate coupled to the backing plate about a peripheral region thereof;
a central support member coupled to an upper surface of the gas distribution plate and extending through the backing plate;
a sealing member disposed between the backing plate and the central support member;
a lift mechanism disposed outside of the pressure tight volume and coupled to the central support member to move the central support member with respect to the backing plate; and
an actuator disposed outside of the pressure tight volume configured to activate the lift mechanism.

2. The process chamber of claim 1, further comprising one or more sensors within the process chamber to detect changes within the process chamber.

3. The process chamber of claim 2, further comprising a controller configured to control the actuator based on signals received from the one or more sensors with respect to detected changes within the process chamber.

4. The process chamber of claim 3, wherein the one or more sensors is selected from the group consisting of a temperature sensor, a position sensor, and a displacement sensor.

5. A process chamber, comprising:
a chamber body having walls, a bottom, and a backing plate defining a pressure tight volume;
a gas distribution plate coupled to the backing plate about a peripheral region thereof;
a first plurality of support members coupled to an upper surface of the gas distribution plate and extending through the backing plate;
a sealing member disposed between each support member and the backing plate, wherein the first plurality of support members are capable of being actuated from outside of the pressure tight volume to move regions of the gas distribution plate coupled to each support member; and
one or more first actuators disposed outside of the pressure tight volume and coupled to at least one of the first plurality of support members for moving the support member with respect to the backing plate.

6. The process chamber of claim 5, wherein each of the first plurality of support members is coupled to at least one of the one or more first actuators.

7. The process chamber of claim 6, further comprising one or more sensors disposed within the process chamber to detect changes within the process chamber and communication with a controller configured to control actuation of the one or more first actuators based on the detected changes.

8. The process chamber of claim 7, wherein the one or more sensors is selected from the group consisting of a temperature sensor, a position sensor, and a displacement sensor.

9. The process chamber of claim 6, wherein the first plurality of support members is coupled to a central region of the upper surface of the gas distribution plate.

10. The process chamber of claim 9, further comprising a second plurality of support members coupled to the upper surface of the gas distribution plate between the central region and the peripheral region and extending through the backing plate.

11. The process chamber of claim 10, further comprising one or more second actuators disposed outside of the pressure tight volume and coupled to the second plurality of support members for moving each of the second plurality of support members with respect to the backing plate.

12. The process chamber of claim 11, further comprising one or more sensors disposed within the process chamber to detect changes within the process chamber and communicate with a controller configured to control actuation of the one or more first actuators and the one or more second actuators based on the detected changes.

13. The process chamber of claim 12, wherein the one or more sensors is selected from the group consisting of a temperature sensor, a position sensor, and a displacement sensor.

14. A method for processing a substrate, comprising:
placing the substrate onto a substrate support opposite a gas distribution plate inside a process chamber;
establishing a vacuum processing condition inside the process chamber;
introducing a process gas into the chamber; and
automatically altering the surface contour of the gas distribution plate without altering the pressure condition within the process chamber.

15. The method of claim 14, further comprising automatically moving a support member coupled to the gas distribution plate and extending through a backing plate of the process chamber.

16. The method of claim 14, wherein the support member comprises a first plurality of support members coupled to a central region of the gas distribution plate.

17. The method of claim 16, further comprising detecting one or more changes within the process chamber and moving one or more of the first plurality of support members based on the detected one or more changes.

18. The method of claim 16, wherein the support member further comprises a second plurality of support members coupled to a region of the gas distribution plate between the central region and the peripheral region.

19. The method of claim 18, further comprising detecting one or more changes within the process chamber and moving one or more of the first or second plurality of support members based on the detected one or more changes.

20. The method of claim 19, wherein detecting one or more changes within the process chamber comprises detecting a temperature change of the gas distribution plate.
